(19) United States
(12) Patent Application Publication
(10) Pub. No.: US 2014/0175488 A1
(43) Pub. Date: Jun. 26, 2014

(54) HEAT-CURABLE SILICONE RESIN SHEET HAVING PHOSPHOR-CONTAINING LAYER AND WHITE PIGMENT-CONTAINING LAYER, METHOD OF PRODUCING LIGHT EMITTING DEVICE USING SAME AND ENCAPSULATED LIGHT EMITTING SEMICONDUCTOR DEVICE PRODUCED THEREBY

(71) Applicant: Shin-Etsu Chemical Co., Ltd., Chiyoda-ku (JP)

(72) Inventors: Tsutomu KASHIWAGI, Annaka-shi (JP); Toshio Shiobara, Annaka-shi (JP)

(73) Assignee: Shin-Etsu Chemical Co., Ltd., Chiyoda-ku (JP)

(21) Appl. No.: 14/083,833

(22) Filed: Nov. 19, 2013

(30) Foreign Application Priority Data
Dec. 21, 2012 (JP) 2012-278895
Oct. 4, 2013 (JP) 2013-208756

(51) Int. Cl. H01L 33/50

(52) U.S. Cl. CPC H01L 33/501
USPC 257/98; 438/27; 428/447; 428/215; 428/323

(57) ABSTRACT

Provided are a heat-curable silicone resin sheet capable of easily and uniformly dispersing phosphors on an LED element surface and reducing a brightness through a light-diffusing effect, a method of producing a light emitting device using the same and an encapsulated light emitting semiconductor device produced by the corresponding method. The heat-curable silicone resin sheet includes at least two layers that are: a phosphor-containing layer consisting essentially of a phosphor-containing heat-curable silicone resin composition that is in a plastic solid or plastic semi-solid state at room temperature; and a white-pigment-containing layer consisting essentially of a white pigment-containing heat-cured silicone resin composition.

### BACKGROUND OF THE INVENTION

1. Field of the Invention

The present invention relates to a heat-curable silicone resin sheet, which may be laminated on and bonded to the chip surface of an LED element, enabling conversion of the wavelength of blue light and ultraviolet light from the LED, and which has at least two silicone resin layers that are: a phosphor-containing layer; and a light diffusing layer containing a white pigment. The present invention also relates to a method of producing a light emitting device utilizing the resin sheet, and the light emitting device obtained by the same method.

2. Description of Related Art

In the field of light emitting diodes (LED) the utilization of phosphors for wavelength conversion is known (JP-A-2005-524737 (Translation of PCT International Application)). Silicone resins are receiving attention as coating materials for the encapsulation and the protection of the LED element due to their excellent light resistance (JP-A-2004-339482).

Generally, in white-colored LED elements, blue light is converted to a quasi-white light by dispersing phosphors in the vicinity of the chip by a method such as coating the LED chip with a silicone resin or an epoxy resin in which phosphors are dispersed. However, since color drift is likely to occur if the dispersion of the phosphors within the resin layer is not uniform or is uneven, it is necessary for the phosphors to be uniformly dispersed within the coating resin layer in order to produce a uniform white light. Consequently, a method in which a silicone resin composition containing phosphors is screen-printed has been investigated, for example. Furthermore, in another investigated method, after application of the composition to the chip followed by uniform dispersion of the phosphors in the vicinity of the chip through precipitation to obtain a phosphor-dispersed layer, a transparent or semi-transparent protective layer is formed on the phosphor-dispersed layer. However, in this method, in addition to an insufficient stability of the quality of the obtained phosphor-dispersed layer and protective transparent layer, the complex production process is a problem. Furthermore, formation of the protective layer is conventionally performed by applying to the LED element a heat-curable silicone resin sheet containing the phosphors, curing the sheet, and injection molding a transparent resin. This method also has a problem that production process is complex.

Electric bulbs using white LEDs have almost prevailed. However, LED electric bulbs are brighter than the conventional ones due to a high brightness thereof regardless of their small-sized light sources, and there are consumers who do not like the fact that the phosphors used in LED electric bulbs look yellow when not lighted. Thus, required are efforts to hide the color of the phosphors when not lighted, by adding a white pigment to a resin layer coating an LED element and thereby reducing the brightness through light diffusion.

Further, as for an LED or the like, required are efforts to hide the color of the phosphors when not lighted or when light diffusion is taking place, by adding a white pigment to a resin layer coating an LED element. In addition, a high heat resistance, a high ultraviolet resistance and the like are also required for such a kind of coating material. Moreover, it is favorable if it is possible to form, with a conventional production apparatus, a resin layer in which phosphors are uniformly dispersed.

### SUMMARY OF THE INVENTION

Therefore, it is an object of the present invention to provide a curable silicone resin sheet capable of easily and uniformly dispersing phosphors on an LED element surface, reducing brightness through a light diffusion effect, and hiding the color of the phosphors when not lighted to achieve a favorable design.

In order to solve the aforementioned problem, a first aspect of the present invention provides a heat-curable silicone resin sheet comprising: a layer (2) consisting essentially of a phosphor-containing heat-curable silicone resin composition that is in a plastically solid or semi-solid state at normal temperate; and a layer (1) consisting essentially of a heat-cured white pigment-containing silicone resin composition.

The heat-curable silicone resin sheet of the present invention can be adhered to an LED element surface, and then cured with heat such that encapsulation can take place.

Further, a second aspect of the present invention provides a method of producing a light emitting device having an LED element. This method comprises: placing on a surface of the LED element the heat-curable silicone resin sheet having the layer (1) and the layer (2), in a manner such that the layer (2) comes in contact with the surface of the LED element; heat-curing the heat-curable silicone resin sheet such that the surface of the LED element can be coated with and encapsulated in a cured product having a phosphor-containing cured silicone resin layer and a white or white, semi-transparent cured silicone resin layer that is phosphor-free but contains a white pigment.

Furthermore, the present invention provides a light emitting device produced by the aforementioned method, in which an LED element is encapsulated in a cured product having: a phosphor-containing cured silicone resin layer (2); and a white pigment-containing cured silicone resin layer (1).

As a particularly preferable example of the heat-curable silicone resin sheet of the present invention, there can be used a heat-curable silicone resin sheet wherein the layer (2) consists essentially of a heat-curable silicone resin composition comprising:

(A) a resin-structured organopolysiloxane essentially consisting of R¹SiO_{1.5} units, R²₂SiO units and R³ₐR⁴_{b}SiO_{(4-a-b)/2} units, wherein each of R¹, R² and R³ independently represents a monovalent hydrocarbon group having 1 to 10, preferably 1 to 6 carbon atoms, such as an alkyl group or cycloalkyl group, for example, a methyl group, an ethyl group, a propyl group or a cyclohexyl group; or a phenyl group, R⁴ independently represents an alkenyl group having 2 to 5, preferably 2 to 3 carbon atoms, such as a vinyl group or an allyl group, a represents 0, 1 or 2, b represents 1 or 2, in which a+b is either 2 or 3, in which at least a portion of the R²₂SiO units is consecutively repeated in a repetition number of 5 to 300;

(B) a resin-structured organohydrogenpolysiloxane essentially consisting of R¹SiO_{1.5} units, R²₂SiO units and R³_{c}H_{d}SiO_{(4-c-d)/2} units, wherein R¹, R² and R³ independently represent the aforementioned groups, c represents 0, 1 or 2, d represents 1 or 2, and c+d is either 2 or 3, and wherein at least a portion of the R²₂SiO units are consecutively repeated in the repetition number of 5 to 300, in such an amount that the molar ratio of the hydrogen atoms bonded to silicon atoms in the component (B) with respect to a sum of the alkenyl groups in the component (A) is in a range of 0.1 to 4.0,

(C) a platinum group metal based catalyst; and

(D) a phosphor, in which a molar ratio of hydrogen atoms bonded to silicon atoms in the component (B) with respect to a sum of the vinyl groups and the allyl groups in the component (A) is in a range of 0.1 to 4.0, and

wherein the layer (1) consists essentially of a heat-cured phosphor-free silicone resin composition comprising:

(E) a vinyl group-containing organopolysiloxane;

(F) an organohydrogenpolysiloxane;

(C) a platinum group metal based catalyst; and

(G) a white pigment.

As for the heat-curable silicone resin sheet (since the sheet has at least two layers, it is hereunder also referred to as a two-layer heat-curable silicone resin sheet for the convenience of the description) of the present invention, since at least one of its layers is a plastic solid or semi-solid in an uncured state, the heat-curable silicone resin sheet can be easily handled and has a good workability, and thus cab be easily laminated and bonded to an LED element surface. Furthermore, since the phosphor-containing layer (2) is plastically solid or semi-solid in an uncured state, the dispersion state of the filled phosphors is stable over time, and a resin layer in which the phosphors are uniformly dispersed can be stably maintained without separation or precipitation of the phosphor from the resin during storage.

In the case of the two-layer heat-curable silicone resin sheet of the present invention, since a phosphor layer and a protective layer (encapsulating layer) can be simultaneously formed by bonding only one sheet to the LED element surface, the productivity is significantly improved, and the mass productivity is excellent. The two-layer heat-curable silicone resin sheet can also be easily laminated and bonded to an LED element surface with a conventional mounting device, such as a die-bond mounter.

Moreover, by curing the composition sheet laminated in this manner, a cured resin layer in which the phosphors are uniformly dispersed can be efficiently and stably formed to have a uniform layer thickness. Furthermore, since the phosphors are uniformly dispersed in the obtained phosphor resin layer (2), a color drift is hard to occur, the color rendering is good, and a uniform white light can be obtained. Moreover, since the cured protective layer (1) contains a white pigment, a light diffusion effect is obtained, glare is reduced, and additionally, at the time of non-illumination, the color of the phosphors are hidden by the white pigment, therefore the appearance is also good.

In a case where the composition of the preferable embodiment mentioned above is utilized, the cured product has an excellent flexibility unlike conventional cured resins, and forms a cured resin layer with a reduced surface tack. Additionally, the composition has an advantage that it is easily moldable with conventional molding apparatuses.

### BRIEF DESCRIPTION OF THE DRAWINGS

FIG. 1 is a cross-sectional view showing the structure of a heat-curable silicone resin sheet of the present invention produced in Example 1.

FIGS. 2A and 2B are schematic views describing the encapsulation of an LED element disposed on a ceramic substrate.

FIGS. 3A and 3B are schematic views describing the encapsulation of an LED element mounted inside a reflector.

FIGS. 4A and 4B are schematic views describing the encapsulation of an LED element bonded by the flip-chip method.

### DETAILED DESCRIPTION OF THE INVENTION

The present invention is described with greater detail hereunder.

A heat-curable silicone resin sheet of the present invention includes at least a layer (1) and a layer (2), in which the layer (2) is either plastically solid or semi-solid at room temperature. Here, a “room temperature” refers to an ambient temperature under a normal condition. That is, a room temperature usually refers to a temperature of 15 to 30° C., and typically to a temperature of 25° C. The term “semi-solid” refers to a state of a substance where the substance is plastic and is capable of maintaining a shape thereof for at least an hour, preferably eight hours or more, once formed into that particular shape. For example, an intrinsically fluid substance having a very high viscosity at room temperature is said to be semi-solid if no change thereof (e.g., no collapse) to a predetermined shape is observed by the naked eye in a short period of time of at least one hour due to its exceedingly high viscosity at room temperature. Since the composition forming the layer (2) is either solid or semi-solid, a favorable handling property and a high workability of the composition can be achieved. Further, a favorable dispersion of phosphors is maintained in the layer (2) over time.

Although the layer (2) of the heat-curable silicone resin sheet of the present invention is in the state of either plastically solid or such semi-solid at room temperature, the layer (2) begins to cure when heated. During a curing process thereof, softening takes place in the beginning. That is, while only a slight fluidity is exhibited when it is in a solid state, a slight increase in fluidity is exhibited when it is in a semi-solid state. The layer (2) finally solidifies as the viscosity thereof increases again.

In the present invention, the layer (2) contains phosphors, converts a wavelength of a light emitted by an LED element to a desired wavelength, and protects and encapsulates the LED element by covering the element with the layer (2). The layer (1) serves to enhance the whiteness of the light emitted from the LED element and to diffuse the light, and is expected to bring about a color-shielding effect on the yellow LED. In addition, the layer (1) serves to further protect the element. In general, a thickness of the layer (2) is preferably 20 to 100 μm, more preferably 30 to 80 μm, in terms of achieving a favorable wavelength conversion property. Further, since a particle diameter of phosphors and/or a dispersion concentration thereof also play a role in determining the thickness of the layer (2), it is desired that the thickness be chosen in consideration of these factors. When an amount of phosphors is too large, it is difficult to, for example, obtain a white light from a blue LED. Further, it is preferred that the layer (2) be not too thin in view of molding operation, in order to obtain a given thickness in which phosphors are evenly dispersed. The thickness of the layer (1) made of a cured resin is preferably 20 to 300 μm, more preferably 30 to 200 μm, in terms of element protection.

In the following description, a composition used for the layer (1) may be referred to as a composition (1), whereas a composition used for the layer (2) may be referred to as a composition (2). Me represents a methyl group, Et represents an ethyl group, Ph represents a phenyl group, and Vi represents a vinyl group.

In the beginning, there are described components that are used in the composition (1) and composition (2) in the preferred examples. Here, descriptions of components that are commonly used for both the composition (1) and the composition (2), can be applied to both the composition (1) and the composition (2) if not otherwise specified.

—(A) Alkenyl Group-Containing Organopolysiloxane Having a Resin Structure—

An organopolysiloxane with a resin structure (i.e., three-dimensional network structure), used as an important component (A) of the composition of the present invention, is a resin-structured organopolysiloxane consisting essentially of R¹SiO_{1.5} units, R²₂SiO units and R³ₐR⁴_{b}SiO_{(4-a-b)/2} (wherein R¹, R², and R³ each represents a monovalent hydrocarbon group having 1 to 10, preferably 1 to 6 carbon atoms, such as an alkyl group or cycloalkyl group, e.g. a methyl group, an ethyl group, a propyl group or a cyclohexyl group; or a phenyl group, R⁴ independently represents an alkenyl group having 2 to 5, preferably 2 to 3 carbon atoms, such as, for example, a vinyl group or an allyl group, a represents 0, 1, or 2, b represents 1 or 2, and a+b is either 2 or 3), and partially includes a structure in which at least a portion of the R²₂SiO units are consecutively repeated with a number of repetitions thereof in a range of 5 to 300, preferably 10 to 300, more preferably 15 to 200, and even more preferably 20 to 100.

Here, the structure in which at least a portion of the R²₂SiO units are consecutively repeated with a number of the repetitions in a range of 5 to 300 is represented by the general formula (1):

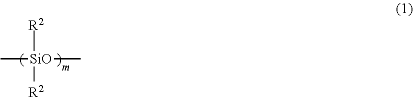

wherein m represents an integer of 5 to 300, and the general formula (1) represents a linear diorganopolysiloxane chain structure.

Preferably at least a portion, and preferably 50 mol % or more (50 to 100 mol %), particularly 80 mol % or more (80 to 100 mol %), of all of the R²₂SiO units which exist within the organopolysiloxane of the component (A) forms a chain structure represented by the general formula (1) within the molecule.

Within the molecule of the component (A), the R²₂SiO units serve to linearly stretch (or extend) the polymer molecule, and the R¹SiO_{1.5} units branch or three-dimensionally network the polymer molecule. The R⁴ (an alkenyl group such as a vinyl group or an allyl group) within the R³ₐR⁴_{b}SiO_{(4-a-b)/2} units achieves a role of curing the composition of the present invention by undergoing a hydrosilylation addition reaction with the hydrogen atoms bonded to the silicon atoms (that is to say, the SiH groups) of the R³_{c}H_{d}SiO_{(4-c-d)/2} units in the component (B) mentioned below.

The molar ratio of the essential three types of siloxane units that constitute the component (A), that is to say, the molar ratio of the R¹SiO_{1.5} units:R²₂SiO units:R³ₐR⁴_{b}SiO_{(4-a-b)/2} units is preferably, for the characteristics of the obtained cured product, 90 to 24:75 to 9:50 to 1, or more particularly, 70 to 28:70 to 20:10 to 2 (provided the sum is 100).

With regard to the R³ₐR⁴_{b}SiO_{(4-a-b)/2} units, it is preferable for the alkenyl groups such as vinyl groups or allyl groups within the organopolysiloxane (A) to exist at a total of 0.001 mol/100 g or more, or more preferably 0.025 mol/100 g or more, or even more preferably 0.03 to 0.3 mol/100 g.

Furthermore, if the polystyrene-equivalent weight-average molecular weight of this component (A) according to gel permeation chromatography (GPC) is in a range of 3,000 to 1,000,000, or particularly 10,000 to 100,000, the polymer of component (A) is in a solid or a semi-solid state and this is preferable in terms of workability, curability and the like.

Such a resin-structured organopolysiloxane (A) can be synthesized by combining the compounds that serve as sources of the respective units so that the produced polymer has each of the three types of siloxane units in a required ratio, and by performing co-hydrolysis-condensation in the presence of an acid, for example.

Examples of the raw material for the R¹SiO_{1.5} units include chlorosilanes such as MeSiCl₃, EtSiCl₃, PhSiCl₃, propyltrichlorosilane, and cyclohexyltrichlorosilane, as well as alkoxysilanes, such as methoxysilanes, that correspond to these respective chlorosilanes.

Examples of the raw material for the R²₂SiO units include the compounds shown below:

### ClMe₂SiO(Me₂SiO)ₙSiMe₂Cl,

### ClMe₂SiO(Me₂SiO)ₘ(PhMeSiO)ₙSiMe₂Cl,

### ClMe₂SiO(Me₂SiO)ₘ(Ph₂SiO)ₙSiMe₂Cl,

### HOMe₂SiO(Me₂SiO)ₙSiMe₂OH,

### HOMe₂SiO(Me₂SiO)ₘ(PhMeSiO)ₙSiMe₂OH,

### HOMe₂SiO(Me₂SiO)ₘ(Ph₂SiO)ₙSiMe₂OH,

### MeOMe₂SiO(Me₂SiO)ₙSiMe₂OMe,

### MeOMe₂SiO(Me₂SiO)ₘ(PhMeSiO)ₙSiMe₂OMe, and

### MeOMe₂SiO(Me₂SiO)ₘ(Ph₂SiO)ₙSiMe₂OMe

wherein m represents an integer of 5 to 150 (average value), and n represents an integer of 5 to 300 (average value).

Furthermore, the R³ₐR⁴_{b}SiO_{(4-a-b)/2} units represent one type of siloxane unit or a combination of two or more siloxane units selected from R³R⁴SiO units, R³₂R⁴SiO_{0.5} units, R⁴₂SiO units, and R³R⁴₂SiO_{0.5} units. As the raw materials thereof, chlorosilanes such as Me₂ViSiCl, MeViSiCl₂, Ph₂ViSiCl, PhViSiCl₂, and alkoxysilanes such as methoxysilanes that respectively correspond to these chlorosilanes can be exemplified.

In the present invention, the expression that the organopolysiloxane of the component (A) “consists essentially of R¹SiO_{1.5} units, R²₂SiO units, and R³ₐR⁴_{b}SiO_{(4-a-b)/2} units” means that 90 mol % or more (90 to 100 mol %), or particularly 95 mol % or more (95 to 100 mol %) of the siloxane units that constitute the component (A) are represented by these three types of siloxane units, and that 0 to 10 mol %, or particularly 0 to 5 mol % may be represented by the other siloxane units. Specifically, at the time the organopolysiloxane of the component (A) is produced by co-hydrolysis and condensation of the raw materials mentioned above, in addition to the R¹SiO_{1.5} units, the R²₂SiO units, and/or the R³ₐR⁴_{b}SiO_{(4-a-b)/2} units, there are cases where siloxane units having silanol groups are formed as a by-product. The organopolysiloxane of the component (A) may be one containing these silanol group-containing siloxane units, in general, at approximately 10 mol % or less (0 to 10 mol %), or preferably 5 mol % or less (0 to 5 mol %) with respect to all of the siloxane units. Examples of the silanol group-containing siloxane units include R¹(HO)SiO units, R¹(HO)₂SiO_{0.5} units, R²₂(HO)SiO_{0.5} units, R³ₐR⁴_{b}(HO)SiO_{(3-a-b)/2} units, and R³ₐR⁴_{b}(HO)₂SiO_{(2-a-b)/2} units (wherein R¹ to R⁴, a and b are each the same as defined above).

### —(B) Organohydrogenpolysiloxane Having a Resin Structure—

The organohydrogenpolysiloxane having a resin structure (that is to say, the three-dimensional network structure) that functions as the important component (B) of the composition of the present invention consists essentially of R¹SiO_{1.5} units, R²₂SiO units, and R³_{c}H_{d}SiO_{(4-c-d)/2} units (wherein R¹, R² and R³ each represent the groups as defined above, c represents 0, 1 or 2, d represents 1 or 2, and c+d is either 2 or 3), and partially contains a linear siloxane structure in which at least a portion of the R²₂SiO is consecutively repeated with a number of repetitions thereof in a range of 5 to 300, or preferably 10 to 300, or more preferably 15 to 200, or even more preferably 20 to 100.

The structure in which at least a portion of the R²₂SiO units is consecutively repeated with a number of repetitions thereof in a range of 5 to 300, as described above in relation to the component (A), denotes that at least a portion of the R²₂SiO units, and preferably 50 mol % or more (50 to 100 mol %), and particularly 80 mol % or more (80 to 100 mol %) of the R²₂SiO units, which exist within the component (B), form a linear diorganopolysiloxane chain structure represented by the general formula (1) within the molecule of the component (B).

Also within the molecule of the component (B), the R²₂SiO units serve to linearly stretch the polymer molecule, and the R¹SiO_{1.5} units act as branch or three-dimensionally network the polymer molecule. The hydrogen atoms bonded to the silicon atoms within the R³_{c}H_{d}SiO_{(4-c-d)/2} units, by undergoing a hydrosilylation addition reaction with the alkenyl groups possessed by the component (A), achieve a role of curing the composition of the present invention.

The molar ratio of the essential three types of siloxane units that constitute the component, (B) that is to say, the molar ratio of the R¹SiO_{1.5} units:R²₂SiO units:R³_{c}H_{d}SiO_{(4-c-d)/2} units is preferably, for the characteristics of the obtained cured product, 90 to 24:75 to 9:50 to 1, or more preferably 70 to 28:70 to 20:10 to 2 (provided the sum is 100).

Furthermore, the polystyrene-equivalent weight-average molecular weight of this component (B) according to GPC is in the range of 3,000 to 1,000,000, or particularly 10,000 to 100,000, is preferable in view of workability, the characteristics of the cured product and the like.

Such a resin-structured organohydrogenpolysiloxane can be synthesized by combining the compounds that serve as the raw materials of the respective units so that the three siloxane units give a required molar ratio within the produced polymer, and performing cohydrolysis-condensation.

Examples of the raw material for the R¹SiO_{1.5} units include MeSiCl₃, EtSiCl₃, PhSiCl₃, propyltrichlorosilane, cyclohexyltrichlorosilane, and alkoxysilanes, such as methoxysilane, that correspond to these respective chlorosilanes.

Examples of the raw material for the R²₂SiO units include the compounds shown below.

### ClMe₂SiO(Me₂SiO)ₙSiMe₂Cl,

### ClMe₂SiO(Me₂SiO)ₘ(PhMeSiO)ₙSiMe₂Cl,

### ClMe₂SiO(Me₂SiO)ₘ(Ph₂SiO)ₙSiMe₂Cl,

### HOMe₂SiO(Me₂SiO)ₙSiMe₂OH,

### HOMe₂SiO(Me₂SiO)ₙ(PhMeSiO)ₙSiMe₂OH,

### HOMe₂SiO(Me₂SiO)ₘ(Ph₂SiO)ₙSiMe₂OH,

### MeOMe₂SiO(Me₂SiO)ₙSiMe₂OMe,

### MeOMe₂SiO(Me₂SiO)ₘ(PhMeSiO)ₙSiMe₂OMe, and

### MeOMe₂SiO(Me₂SiO)ₘ(Ph₂SiO)ₙSiMe₂OMe

wherein, m represents an integer of 5 to 150 (average value), and n represents an integer of from 5 to 300 (average value).

Furthermore, the R³_{c}H_{d}SiO_{(4-c-d)/2} units represent one type of siloxane unit or an desired combination of two or more siloxane units selected from among R³HSiO units, R³₂HSiO_{0.5} units, H₂SiO units, and R³H₂SiO_{0.5} units, and as the raw materials thereof, chlorosilanes such as Me₂HSiCl, MeHSiCl₂, Ph₂HSiCl, PhHSiCl₂, and alkoxysilanes such as methoxysilanes that respectively correspond to these chlorosilanes can be exemplified.

In the present invention, the expression that the organohydrogenpolysiloxane of the component (B) “consists essentially of R¹SiO_{1.5} units, R²₂SiO units, and R³_{c}H_{d}SiO_{(4-c-d)/2} units” means that 90 mol % or more (90 to 100 mol %), or particularly 95 mol % or more (95 to 100 mol %) of the siloxane units that constitute the component (B) are represented by these three types of siloxane units, and that 0 to 10 mol %, or particularly 0 to 5 mol % may be represented by the other siloxane units. Specifically, at the time the organopolysiloxane of the component (B) is produced by the co-hydrolysis and the condensation of the starting materials mentioned above, in addition to the R¹SiO_{1.5} units, the R²₂SiO units, and the R³_{c}HₐSiO_{(4-c-d)/2} units, there are cases where siloxane units having silanol groups are formed via a secondary reaction. The organohydrogenpolysiloxane of the component (B) may be one containing these silanol group-containing siloxane units, in general, at approximately 10 mol % or less (0 to 10 mol %), or preferably 5 mol % or less (0 to 5 mol %) with respect to all of the siloxane units. Examples of the silanol group-containing siloxane units include R¹(HO)SiO units, R¹(HO)₂SiO_{0.5} units, R²₂(HO)SiO_{0.5} units, R³_{c}H_{d}(HO)SiO_{(3-c-d)/2} units, and R³_{c}H_{d}(HO)₂SiO_{(2-c-d)/2} units (wherein R¹ to R³, c and d are each the same as defined above).

The amount of the added organohydrogenpolysiloxane of the component (B) is such that the molar ratio of the hydrogen atoms bonded to silicon atoms (SiH groups) within the component (B) with respect to the total amount of vinyl groups and allyl groups within the component (A) is 0.1 to 4.0, preferably 0.5 to 3.0, more preferably 0.8 to 2.0. If this ratio is less than 0.1, the curing reaction does not proceed, and it is difficult to obtain a silicone cured product. The ratio exceeding 4.0 will lead to change the physical properties of the cured product over time since a large amount of unreacted Sill groups remains within the cured product.

### —(C) Platinum Group Metal-Comprising Catalyst—

This catalyst component is one that is added in order to promote the addition curing reaction of the composition of the present invention, and the examples include platinum-based, palladium-based, or rhodium-based catalysts. From the standpoint of cost, platinum systems such as platinum, platinum black, and chloroplatinic acid, for example, H₂PtCl₆.mH₂O, K₂PtCl₆, KHPtCl₆.mH₂O, K₂PtCl₄, K₂PtCl₄.mH₂O, PtO₂.mH₂O (m represents a positive integer), and complexes of these with hydrocarbons such as olefins, alcohols, or vinyl groups-containing organopolysiloxanes can be exemplified as the catalyst. These catalysts can be utilized alone as a single type or as a combination of two or more types.

The amount of the added component (C) may be an effective amount for curing, and generally, in terms of the mass of the platinum group metal relative to the total mass of the components (A) and (B), in the range of 0.1 to 500 ppm, preferably 0.5 to 100 ppm.

### —(D) Phosphors—

Any known phosphors may be used as the phosphors of the component (D), and the amount added thereof is in general preferably in a range of 0.1 to 300 parts by mass, more preferably in a range of 1 to 300 parts by mass, and even more preferably in a range of 1 to 100 parts by mass per 100 parts by mass of the combination of the components (A) and (B) within the composition (2) composing the phosphor-containing layer (2). The average particle diameter of the phosphors of the component (D) can be evaluated as a mass average value D₅₀ (or median size) of a particle size distribution measurement by means of a laser optical diffraction method. Generally, it is acceptable if the average particle diameter thereof is 10 nm or larger, and those that are preferably 10 nm to 10 μm, or more preferably 10 nm to 1 μm are utilized.

It is acceptable if the phosphor material is one that absorbs the light from a semiconductor light emitting diode having a nitride type semiconductor as the light emitting layer, and performs wavelength conversion of the light to a different wavelength. It is preferable if it is at least one or more selected from among nitride-based phosphors and oxynitride-based phosphors that are primarily activated by lanthanoid elements such as Eu and Ce; alkaline earth metal halogen apatite phosphors, alkaline earth metal halogen borate phosphors, alkaline earth metal aluminate phosphors, alkaline earth metal silicate phosphors, alkaline earth metal sulfide phosphors, alkaline earth metal thiogallate phosphors, alkaline earth metal silicon nitride phosphors, and germanate phosphors that are primarily activated by lanthanoid elements, such as Eu, or transition metal elements, such as Mn; rare earth aluminate phosphors or rare earth silicate phosphors that are primarily activated by lanthanoid elements, such as Ce; or organic or organic complex phosphors that are primarily activated by lanthanoid elements, such as Eu; and Ca—Al—Si—O—N based oxynitride glass phosphors. Although the phosphors mentioned below can be utilized as a specific example, it is in no way limited thereto. Hereunder, M represents at least one type of the elements selected from among Sr, Ca, Ba, Mg and Zn, X represents at least one type of the elements selected from among F, Cl, Br and I, and R represents Eu, Mn or a combination of Eu and Mn.

An example of the nitride-based phosphor that is primarily activated by lanthanoid elements, such as Eu and Ce, includes M₂Si₅N₈:Eu. Furthermore, in addition to M₂Si₅N₈:Eu, examples also include MSi₇N₁₀:Eu, M_{1.8}Si₅O_{0.2}N₈:Eu, and M_{0.9}Si₇O_{0.1}N₁₀:Eu.

An example of the oxynitride-based phosphor that is primarily activated by lanthanoid elements, such as Eu and Ce, includes MSi₂O₂N₂:Eu.

An example of the alkaline earth metal halogen apatite phosphor that is primarily activated by lanthanoid elements, such as Eu, or by transition metal elements such as Mn, includes M₅(PO₄)₃X:R.

An example of the alkaline earth metal silicate halogen phosphor includes M₂B₅O₉X:R (M represents at least one element selected from among Sr, Ca, Ba, Mg and Zn. X represents at least one element selected from among F, Cl, Br and I, and R represents at least one of Eu, Mn, and a combination of Eu and Mn.).

Examples of the alkaline earth metal aluminate phosphor include SrAl₂O₄:R, Sr₄Al₁₄O₂₅:R, CaAl₂O₄:R, BaMg₂Al₁₆O₂₇:R, BaMg₂Al₁₆O₁₂:R, and BaMgAl₁₀O₁₇:R(R represents at least one of Eu, Mn, and a combination Eu and Mn).

Examples of the alkaline earth metal sulfide phosphor include La₂O₂S:Eu, Y₂O₂S:Eu, and Gd₂O₂S:Eu.

Examples of a rare earth aluminate phosphor that is primarily activated by lanthanoid elements, such as Ce, include YAG phosphors represented by the compositional formula such as Y₃Al₅O₁₂:Ce, (Y_{0.8}Gd_{0.2})₃Al₅O₁₂:Ce, Y3(Al_{0.8}Ga_{0.2})₅O₁₂:Ce, and (Y,Gd)₃(Al,Ga)₅O₁₂. Furthermore, the examples also include Tb₃Al₅O₁₂:Ce and Lu₃Al₅O₁₂:Ce, in which a portion or all of the Y has been substituted by Tb, Lu or the like.

Examples of other phosphors include ZnS:Eu, Zn₂GeO₄:Mn and MGa₂S₄:Eu.

The phosphors mentioned above may, as desired, be made to contain one or more elements selected from among Tb, Cu, Ag, Au, Cr, Nd, Dy, Co, Ni and Ti, instead of Eu, or in addition to Eu.

The Ca—Al—Si—O—N based oxynitride glass phosphors are phosphors comprising 20 to 50 mol % of CaCO₃ calculated as CaO, 0 to 30 mol % of Al₂O₃, 25 to 60 mol % of SiO, 5 to 50 mol % of AlN, and 0.1 to 20% of a rare earth oxide or a transition metal oxide, in which the total of the five components amounts to 100 mol %. In the phosphors in which an oxynitride glass is contained as a parent material, it is preferable that the nitrogen content is 15 mass % or less, and it is preferable for the phosphor glass to include, in addition to the rare earth oxide ions, the other rare earth element ions that serve as a sensitizing agent, in the form of rare earth oxides at a content in the range of 0.1 to 10 mol % as a co-activator agent.

Furthermore, phosphors other than the phosphors mentioned above can also be utilized as far as they exhibit similar performance and effect.

### —(E) Vinyl Group-Containing Organopolysiloxane—

(E) is an organopolysiloxane having within each molecule two or more aliphatic unsaturated bonds such as a vinyl group, an allyl group or the like of 2 to 8 carbon atoms, particularly an alkenyl group of 2 to 6 carbon atoms, and exhibiting a viscosity of 10 to 1,000,000 mPa·s, particularly 100 to 100,000 mPa·s at a temperature of 25° C. Specifically, it is desired, in view of workability, curability or the like, that this organopolysiloxane be a linear organopolysiloxane represented by the general formula (2) below, having at least one alkenyl group on each of the silicon atoms at both molecular chain terminals, and exhibiting the viscosity of 10 to 1,000,000 mPa·s at 25° C. as described above. Here, this linear organopolysiloxane may also contain in its molecular chain a small amount of branched structures (trifunctional siloxane units), e.g. an amount occupying 20 mol % or less of the entire (E) vinyl group-containing organopolysiloxane.

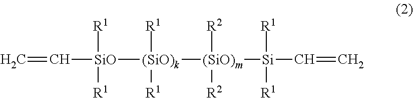

(In the formula (2), R¹ represents identical or different, unsubstituted or substituted monovalent hydrocarbon groups; R² represents identical or different, unsubstituted or substituted monovalent hydrocarbon groups having no aliphatic unsaturated bonds; each of k and m represents 0 or a positive integer; k+m is a number that makes the viscosity of this organopolysiloxane at 25° C. fall within the range of 10 to 1,000,000 mPa·s.)

Here, it is preferred that a monovalent hydrocarbon group represented by R¹ have 1 to 10 carbon atoms, more preferably 1 to 6 carbon atoms. Specifically, such monovalent hydrocarbon group may be: an alkyl group such as a methyl group, an ethyl group, a propyl group, an isopropyl group, a butyl group, an isobutyl group, a tert-butyl group, a pentyl group, a neopentyl group, a hexyl group, a cyclohexyl group, an octyl group, a nonyl group or a decyl group; an aryl group such as a phenyl group, a tolyl group, a xylyl group or a naphthyl group; an aralkyl group such as a benzyl group, a phenyl ethyl group or a phenyl propyl group; an alkenyl group such as a vinyl group, an allyl group, a propenyl group, an isopropenyl group, a butenyl group, a hexenyl group, a cyclohexenyl group or an octenyl group; or a group in which some or all of the hydrogen atoms within one of the above hydrocarbon groups have been substituted with a halogen atom such as a fluorine atom, bromine atom or chlorine atom, or with a cyano group or the like, for example, a halogenated alkyl group such as a chloromethyl group, chloropropyl group, bromoethyl group or trifluoropropyl group, or a cyanoethyl group.

Further, it is preferred that the monovalent hydrocarbon group represented by R² has 1 to 10 carbon atoms, more preferably 1 to 6 carbon atoms. Specific examples of R² are similar to those of R¹ except that alkenyl group is not included.

Each of k and m is in general either 0 or a positive integer satisfying 0≦k+m≦10,000. Preferably, k and m are integers satisfying 5≦k+m≦2,000 and 0<k/(k+m)≦0.2.

Specific examples of the component (E) are as follows.

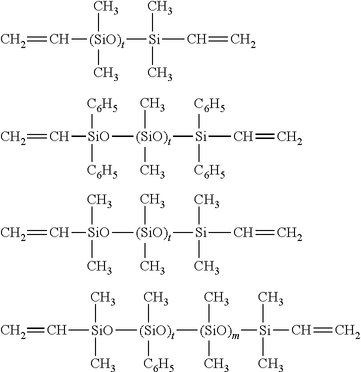

(In the above formula, each oft and m represents an integer of 8 to 2,000.)

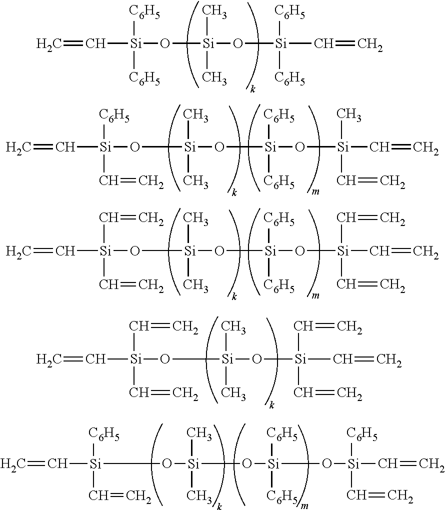

(In the above formula, k, m are numbers as defined above)

Specific examples of the component (E) are as follows.

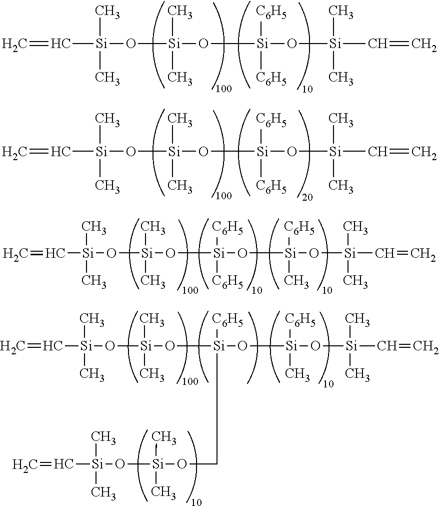

A resin-structured organopolysiloxane can also be used in combination with the aforementioned organopolysiloxane.

An organopolysiloxane with the resin structure (i.e., three-dimensional network structure) is a resin-structured organopolysiloxane consisting essentially of SiO₂ units, R³ₙR⁴ₚSiO_{0.5} units and R³_{q}R⁴ᵣSiO_{0.5} units (wherein in the above formulas, R³ represents a vinyl group or a allyl group, R⁴ represents a monovalent hydrocarbon group having no aliphatic unsaturated bonds, n represents 2 or 3, p represents 0 or 1, n+p=3, q represents 0 or 1, r represents 2 or 3, and q+r=3)

Monovalent hydrocarbon groups represented by R⁴ include those having 1 to 10 carbon atoms, particularly 1 to 6 carbon atoms, as is the case of R² in the formula (2). Specific examples of R⁴ include those of 1Z¹ (except the alkenyl groups).

Here, it is preferred, in molar ratio, that

(b+c)/a=0.3 to 3, particularly 0.7 to 1

c/a=0.01 to 1, particularly 0.07 to 0.15, wherein the SiO₂ units are represented by units a, the R³ₙR⁴ₚSiO_{0.5} units are represented by units b, and the R³_{q}R⁴ᵣSiO_{0.5} units are represented by units c. Further, it is preferred that the weight-average molecular weight of this organopolysiloxane be within a range of 500 to 10,000.

In addition to the units a, units b and units c, this resin-structured organopolysiloxane may also further contain a small amount of difunctional siloxane units or trifunctional siloxane units (i.e., organosilsesquioxane units) as far as the object of the present invention is not be impaired.

This type of resin-structured organopolysiloxane can be easily synthesized by combining together the compounds serving as individual unit sources in such a way that the aforementioned molar ratios are achieved, and then performing co-hydrolysis in the presence of, for example, an acid.

Here, sources of the units a include silicate soda, alkyl silicate, polyalkyl silicate, silicon tetrachloride and the like.

Further, examples of sources of the units b are as follows.

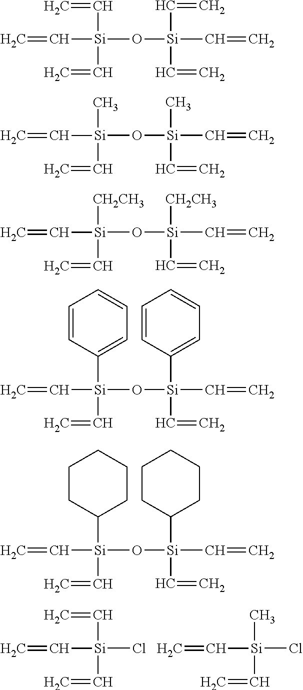

Furthermore, examples of sources of the units c are as follows.

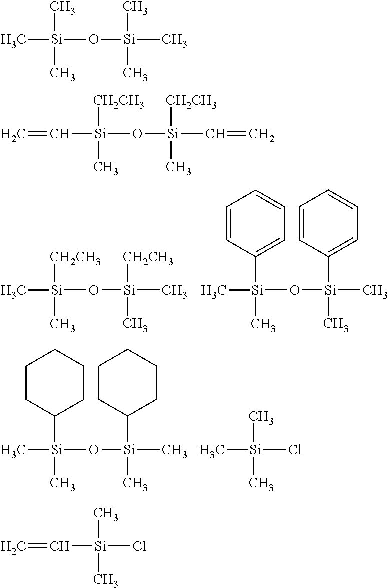

The aforementioned resin-structured organopolysiloxane is added to improve a physical strength and a surface tack property of the cured product. Preferably, this resin-structured organopolysiloxane is added in an amount of 20 to 70% by mass with respect to a total amount of the component (E). Particularly, it is more preferred that this resin-structured organopolysiloxane be added in an amount of 30 to 60% by mass. When the amount of this resin-structured organopolysiloxane added is too small, the aforementioned effects cannot be achieved sufficiently. Meanwhile, when it is too large, there occur problems such as a significant increase in the viscosity of the composition and a higher likelihood of crack occurrence in the cured product.

### —(F) Organohydrogenpolysiloxane—

An organohydrogenpolysiloxane as a component (F) functions as a crosslinking agent. Here, a cured product is obtained through an addition reaction between the SiH groups in this component and the vinyl groups in the component (E). This organohydrogenpolysiloxane can be any type of organohydrogenpolysiloxane having two or more hydrogen atoms bonded to silicon atoms (i.e. SiH groups) within each molecule. Particularly, this organohydrogenpolysiloxane may be that represented by the following average composition formula (3), and having at least two, preferably three or more hydrogen atoms bonded to silicon atoms (i.e. SiH groups) within each molecule.

Hₐ(R⁵)_{b}SiO_{(4-a-b)/2} (3)

(In this formula, R⁵ represents identical or different, unsubstituted or substituted monovalent hydrocarbon groups having no aliphatic unsaturated bonds; a and b are numbers satisfying 0.001≦a≦2, 0.7≦b≦2, and 0.8≦a+b≦3.)

Here, R⁵ in the above formula (3) represents identical or different, unsubstituted or substituted monovalent hydrocarbon groups having no aliphatic unsaturated bonds but having 1 to 10, more preferably 1 to 7 carbon atoms. R⁵ may be a lower alkyl group such as a methyl group, an aryl group such as a phenyl group or that selected from the examples of the substituent group R² in the aforementioned general formula (1). Further, a and b are numbers satisfying 0.001≦a≦2, 0.7≦b≦2, and 0.8≦a+b≦3, preferably numbers satisfying 0.05≦a≦1, 0.8≦b≦2, and 1≦a+b≦2.7. Furthermore, no particular restrictions are imposed on the locations of the hydrogen atoms bonded to silicon atoms. In fact, such hydrogen atoms may be located at the terminals of a molecular chain or in the non-terminals.

As such organohydrogenpolysiloxane (F), there can be used, for example, 1,1,3,3-tetramethyldisiloxane, 1,3,5,7-tetramethylcyclotetrasiloxane, methylhydrogenpolysiloxane with both terminals blocked with trimethylsiloxy groups, copolymers of dimethylsiloxane and methylhydrogensiloxane with both terminals blocked with trimethylsiloxy groups, dimethylpolysiloxane with both terminals blocked with dimethylhydrogensiloxy groups, copolymers of dimethylsiloxane and methylhydrogensiloxane with both terminals blocked with dimethylhydrogensiloxy groups, copolymers of methylhydrogensiloxane and diphenylsiloxane with both terminals blocked with trimethylsiloxy groups, copolymers of methylhydrogensiloxane, diphenylsiloxane and dimethylsiloxane with both terminals blocked with trimethylsiloxy groups, copolymers composed of (CH₃)₂HSiO_{1/2} units and SiO_{4/2} units, or copolymers composed of (CH₃)₂HSiO_{1/2} units, SiO_{4/2} units and (C₆H₅)₃SiO_{3/2} units.

Further, there can also be used a compound represented by the following structure.

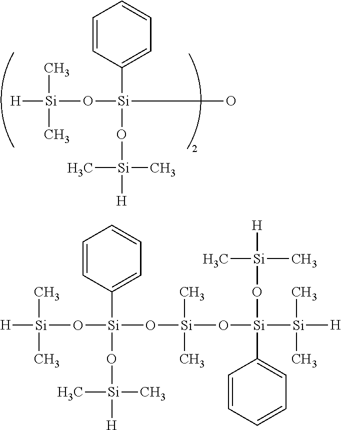

While the molecular structure of this organohydrogenpolysiloxane (F) may be a linear structure, a cyclic structure, a branched structure or a three-dimensional network structure, the number of silicon atoms within each molecule (or polymerization degree) of this organohydrogenpolysiloxane may be about 3 to 1,000, particularly about 3 to 300.

The organohydrogenpolysiloxane (F) can usually be prepared by either hydrolyzing a chlorosilane such as R⁵SiHCl₂, (R⁵)₃SiCl, (R⁵)₂SiCl₂, (R⁵)₂SiHCl (R⁵ is defined as above), and equilibrating the resulting siloxane through hydrolysis.

The amount of the organohydrogenpolysiloxane (F) added is an effective amount for curing the components (E) and (F). Particularly, a molar ratio of the SiH groups of the component (F) to a total amount of the alkenyl groups (e.g. vinyl groups) in the component (E), may be 0.1 to 4.0, preferably 1.0 to 3.0, and more preferably 1.2 to 2.8. When this molar ratio is lower than 0.1, the curing reaction does not proceed, thereby making it difficult to obtain a cured product of a silicone rubber. Meanwhile, when this molar ratio is greater than 4.0, a large amount of unreacted SiH groups will remain in the cured product, thus causing a rubber property to change over time in some cases.

### —(G) White Pigment—

A white pigment is added into the silicone resin composition of the present invention. The white pigment of the component (G) is added as a light diffusing material and furthermore, as a white colorant in order to increase the whiteness, and as the white pigment, titanium dioxide, alumina, rare earth oxides represented by yttrium oxide, barium sulfate, potassium titanate, zirconium oxide, zinc sulfide, zinc sulfate, zinc oxide, magnesium oxide and the like can be used alone or as a combination of several types. In order to increase the compatibility and dispersibility between the resin and the inorganic fillers, the white pigments can be surface-treated beforehand with a hydrous oxide of Al and Si for example. It is preferable to use titanium dioxide as the white pigment, and the unit cell (unit lattice) of this titanium dioxide may be any one selected from the rutile type, the anatase type or the brucite type. Furthermore, the average particle diameter and shape are in no way limited, but the average particle diameter is preferably 50 nm to 5.0 μm. The average particle diameter can be evaluated as a mass average value D₅₀ (or median size) of a particle size distribution measurement by means of the laser optical diffraction method.

The addition of the white pigment within the component that constitutes the white pigment-containing layer (1) is preferably in a range of 0.05 to 10 parts by mass, or more preferably in a range of 0.1 to 5 parts by mass per 100 parts by mass of the component (E) and the component (F). If it is too little, there are cases where a sufficient light diffusion cannot be achieved. Furthermore, if it exceeds 10 parts by mass, the effect of blocking light may be so large as to decrease the brightness.

In a white or a white semi-transparent cured silicone resin layer containing essentially no phosphors and containing the white pigment, in the visible region, or more particularly, at least in the wavelength region of 400 to 500 nm, or preferably 400 to 600 nm, or more preferably in the 400 to 800 nm region, the light transmittance is preferably 50% or less, preferably 40 to 0.1%, and more preferably 30 to 0.5%. Here, the light transmission is defined by the ratio I/I₀ (%) (wherein I₀ represents the strength of the incident light, and I represents the strength of the transmitted light) of the transmitted light strength relative to the incident light strength for light of a given specific wavelength for a sample sheet with a thickness of 100 μm.

### —Other Components—

In addition to the components mentioned above, all types of additives that are themselves known may also be added to the composition of the present invention as needed.

### •Inorganic Filler:

An inorganic filler can be added to the layer (1) and/or the layer (2) with an object of reducing the thermal expansion coefficient. Examples of the inorganic filler include reinforcing inorganic fillers such as fumed silica, and non-reinforcing inorganic fillers such as fused silica and calcium silicate. These inorganic fillers may, in total, be appropriately added in a range of 100 parts by mass or less (0 to 100 parts by mass) per total amount of 100 parts by mass of the components (E) and (F), and in a range in which the objects and the effects of the present invention are not compromised.

### •Adhesion Assistant:

Furthermore, in order to impart adhesivity, an adhesion assistant may be added as needed to the composition of the present invention. Examples of the adhesion assistant include linear or cyclic organosiloxane oligomers with approximately 4 to 50, or preferably approximately 4 to 20 silicon atoms containing within a single molecule at least two types, or preferably two types or three types of functional groups selected from a hydrogen atom bonded to a silicon atom (a SiH group), an alkenyl group bonded to a silicon atom (a Si—CH═CH₂ group for example), an alkoxysilyl group (a trimethoxysilyl group for example), and an epoxy group (a glycidoxypropyl group or a 3,4-epoxycyclohexylethyl group for example), and an organooxysilyl-modified isocyanurate compound expressed by the general formula (4) and/or a hydrolysis-condensation products thereof (organosiloxane-modified isocyanurate compound).

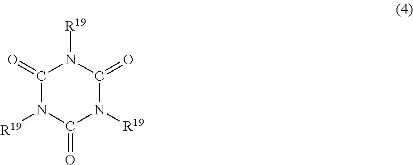

(In the above formula, R¹⁹ represents an organic group represented by formula (5) shown below:

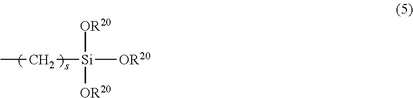

wherein R²⁰ represents a hydrogen atom or a monovalent hydrocarbon with 1 to 6 carbon atoms, s represents an integer of 1 to 6, and particularly 1 to 4), or a monovalent hydrocarbon group comprising an aliphatic unsaturated bond, provided that at least one of the R¹⁹ groups is an organic group represented by formula (5).)

Examples of the monovalent hydrocarbon group comprising an aliphatic unsaturated bond represented by R¹⁹ in the general formula (4) include alkenyl groups with 2 to 8, or particularly 2 to 6 carbon atoms, such as a vinyl group, an allyl group, a propenyl group, an isopropenyl group, a butenyl group, an isobutenyl group, a pentenyl group, and a hexenyl group, and cycloalkenyl groups with 6 to 8 carbon atoms, such as a cyclohexenyl group. Furthermore, examples of the monovalent hydrocarbon group of R²⁰ in formula (5) include alkyl groups, such as a methyl group, an ethyl group, a propyl group, an isopropyl group, a butyl group, an isobutyl group, a tert-butyl group, a pentyl group, a hexyl group, and a cyclohexyl group; alkenyl groups and cycloalkenyl groups as exemplified with regard to R¹⁹ above, and additionally, monovalent hydrocarbon groups with 1 to 8, or particularly 1 to 6 carbon atoms, such as aryl groups like a phenyl group, and R²⁰ is preferably an alkyl group.

Furthermore, as the adhesion assistant, 1,5-glycidoxypropyl-1,3,5,7-tetramethylcyclotetrasiloxane, 1-glycidoxypropyl-5-trimethoxysilylethyl-1,3,5,7-tetramethylcyclotetrasiloxane, and the compounds represented by the formulas below, are exemplified.

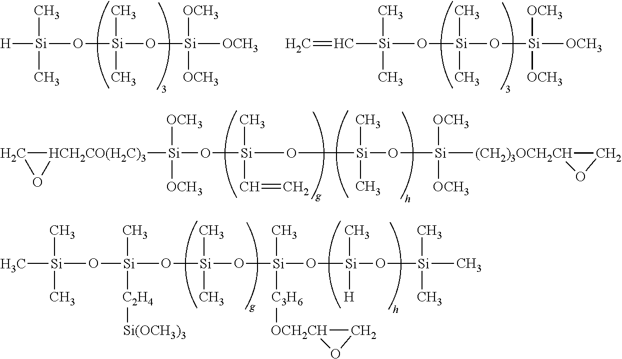

(In the above formulas, each of g and h represents a positive integer in a range of 0 to 50, provided that additionally satisfy g+h is 2 to 50, and preferably 4 to 20.)

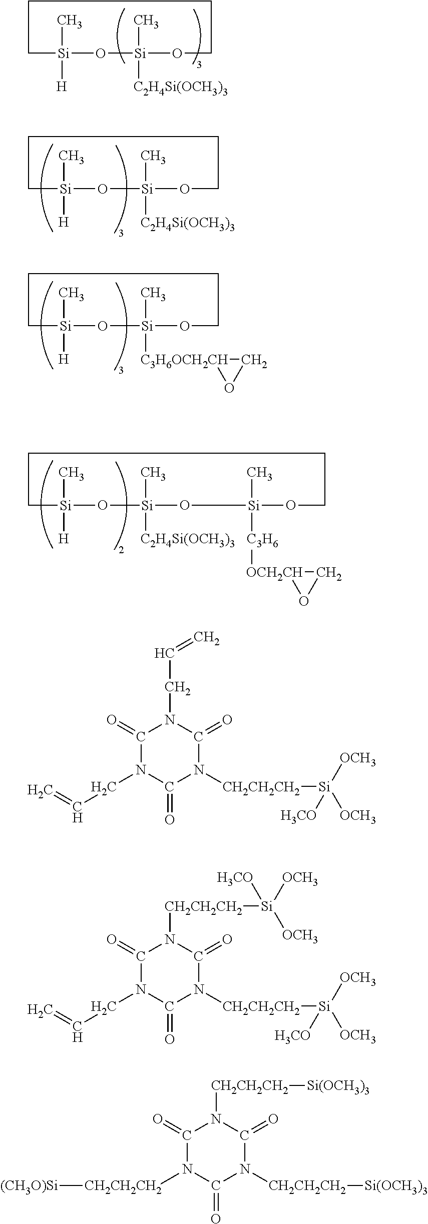

Among the organic silicon compounds mentioned above, the compounds that afford particularly good adhesivity to the obtained cured product are organic silicon compounds having a silicon atom-bonded alkoxy group, and an alkenyl group or a silicon atom-bonded hydrogen atom (a SiH group) within a single molecule.

For the amount added of the adhesion assistant is generally 10 parts by mass or less (that is to say, 0 to 10 parts by mass), and is preferably 0.1 to 8 parts by mass, and more preferably approximately 0.2 to 5 parts by mass, per 100 parts by mass of the component (A). If it is too much, there is a concern that adverse effects will be exerted on the hardness of the cured product, or that the surface tack will be increased.

Furthermore, a liquid silicone component can be added as required to an extent that the heat-curable silicone resin sheet of the present invention is maintained as a solid to semi-solid at room temperature and does not turn liquid. As such a liquid silicone component, one that has a viscosity of approximately 1 to 100,000 mPa·s at room temperature (25° C.) is preferable, and examples include vinylsiloxanes, hydrogensiloxanes, alkoxysilanes, hydroxysiloxanes and their mixtures. The added amount should meet the condition that the silicone composite sheet is maintained as a solid to semi-solid at room temperature, and is generally 50 mass % or less with respect to the whole silicone composite sheet.

### •Reaction Inhibitor:

An appropriate reaction inhibitor can be added to the composition of the present invention as required. The reaction inhibitor inhibits the curing reaction due to hydroxylation, and is added to improve the preservability. Examples of the reaction inhibitor include compounds selected from the group including high vinyl group content organopolysiloxanes, such as tetramethyltetravinylcyclotetrasiloxane, triallylisocyanurates, alkylmaleates, acetylene alcohols and their silane modified compounds and siloxane modified compounds, hydroperoxides, tetramethylethylenediamine, benzotriazole, and mixtures of these. The reaction inhibitor added is generally in a range of 0.001 to 1.0 parts by mass, preferably 0.005 to 0.5 parts by mass per 100 parts by mass of the component (A).

As a typical example of the composition of the present invention, a two-layer silicone resin sheet in which a phosphor-containing silicone resin sheet consisting essentially of the components (A) to (D), and a white pigment-containing silicone cured resin sheet consisting essentially of the components (E), (F), (C) and (G) are bonded together can be given.

—Preparation and Curing Conditions—

By uniformly mixing the components (A) to (D) and optional components for the composition (2), and the components (E), (F), (C), (G) and optional components for composition (1), the compositions (2) and (1) utilized for the production of the silicone resin sheet of the present invention are prepared. Generally, the compositions (1) and (2) are separately stored as two liquids so that the curing does not proceed, and the two liquids are mixed at the time of use before proceeding to the next process. Of course, a reaction inhibitor such as an acetylene alcohol may be added in a small amount so that the two compositions can be provided as one liquid.

In order to produce the two-layer-laminated silicone resin sheet of the present invention, the phosphor-containing silicone resin composition (2) is processed on a release film into a sheet form by a film coater or a hot pressing machine. Next, the white heat-curable silicone resin composition (1) containing a white pigment is processed on the layer of the composition (2) into a sheet form by a film coater or a hot pressing machine. A temperature at that time is a temperature at which the layer (2) will not be cured. Further, the curability of the layer (1) at low temperature is increased in advance such that the layer (1) can be cured at a temperature at which the layer (2) is not cured.

Generally, the silicone resin composition containing phosphors is processed into a sheet form with a film coater or the like at a sheet thickness of preferably 20 to 100 μm.

On the other hand, the white silicone resin composition (1) containing the white pigment is processed into a sheet form by the same method, and the sheet thickness is preferably 20 to 300 μm. If it is too thin, it is not possible to protect an element or gold wires that electrically connect the element and the leads, from external forces. As a protective layer, it is sufficient if it has a thickness of 300 μm, and if it is too thick, the light transmissibility thereof will decrease, thus being undesirable.

Further, it is desired that the properties of the cured product of the white silicone resin composition (1) containing the white pigment be those of a rubber. As for a hardness of such cured product, it is preferred that a value measured using an A-type spring testing machine compliant with JIS K 6301 be 10 to 90, more preferably 20 to 80. When the hardness is 10 or greater, the sheet exhibits, for example, a favorable shape retention property. When the hardness is 90 or lower, a favorable moldability and/or a favorable property to conform with element(s) can be achieved.

Furthermore, as another method, a film is firstly prepared with the phosphor-containing silicone resin composition (2), and the white pigment-containing heat-curable silicone resin composition (1) can be prepared on the film by processing the composition (1) into a sheet form through spray coating. The produced two-layer silicone resin sheet is generally frozen and stored.

As examples of methods for encapsulating the LED element using the two-layer heat-curable silicone resin sheet obtained here, the following methods are described.

For example, as shown in FIG. 2A and FIG. 2B (FIG. 2A is a conceptual cross-sectional view showing a state of a sheet 11 about to be bonded to a ceramic substrate 5 on which LED elements 3 are mounted, and FIG. 2B is a conceptual cross-sectional view showing a state of the completed adhesion), following bonding of blue color LED elements 3 on a ceramic substrate 5 having an external connection terminal (not shown in the drawing) with a resin die-bond agent, the external connection terminal and the LED elements 3 are connected through gold wires 4. In order to encapsulate an LED device of this form, the two-layer silicone resin sheet of the present invention is bonded so that it coats the entire LED-mounted substrate, and encapsulated entire LED elements are cured by heating.

Although the silicone resin sheet 11 of the present invention is cured by heating, since it temporarily softens in the curing process, and the viscosity increases and proceeds towards solidification thereafter, it is possible to perform the encapsulation without imparting damage to the gold wires 4 even if the sheet 11 is bonded to the gold wires 4. Generally, a substrate 5 on which a plurality of LED elements 3 are mounted and encapsulated by this method is diced into separate pieces after the LED elements are coated with the silicone resin sheet and encapsulated with the cured resin. Even in an LED device in which the connection with the external terminal is connected with gold bumps instead of gold wires, it can be encapsulated in the same manner as the case of a gold wire connection.

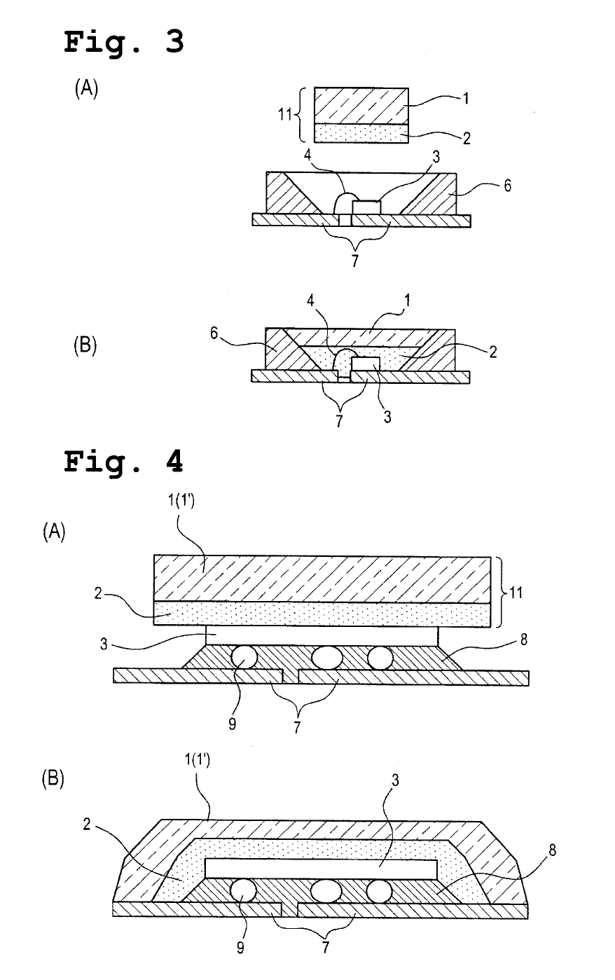

Furthermore, in the case of an LED element mounted within a reflector 6, as shown in FIG. 3A and FIG. 3B (FIG. 3A is a cross-sectional view conceptually showing a state in which a sheet 11 of the present invention is attempted to be bonded to an external lead 7, and FIG. 3B is a cross-sectional view conceptually showing a state in which it is bonded), the silicone resin sheet 11 including two layers is bonded so that the sheet 11 can coat the gold wire 4 connecting the LED element 3 and the external lead 7 before the sheet is cured by heating to encapsulate the LED element.

Since the cured silicone resin forms a flexible cured product with a high hardness and no surface tack, and includes a silicone resin layer containing phosphors and a silicone resin layer containing a white pigment, it is possible to convert the blue light emitted from the LED to a uniform white light without color drift. In addition, since the white light can be diffused by the white pigment-containing silicone resin layer, it is possible to emit a soft light that is gentle to the eyes. Furthermore, since the phosphor-containing silicone resin layer can be concealed by the white pigment-containing silicone resin layer, the color of the phosphor-containing silicone resin layer is not visually recognized even at the time of non-illumination, and thus it becomes possible to produce an LED with a high aesthetic quality.

In a case where the substrate and the LED element are bonded in a flip-chip method, as shown in FIG. 4A and FIG. 4B, following bonding of the LED element 3 and the external lead 7 using a gold bump 9 or the like, an underfill material 8 including a silicone resin containing silica or the like, or an epoxy resin is injected and cured, and the protection of the bump 9 and the element 3 is performed. Thereafter, a silicone resin sheet 11 including the two layers is bonded to the LED element 3 and the sheet is cured by heating. The color shade and the encapsulated shape can be controlled by adjusting the thickness of the phosphor-containing silicone resin layer 2 and the white pigment-containing silicone resin layer 1.

The pressure bonding of the two-layer silicone resin sheet onto the LED element can, in general, be performed at room temperature to 300° C. or less and under a pressure of 10 MPa or less (generally 0.01 to 10 MPa), and preferably 5 MPa or less (0.1 to 5 MPa for example), and particularly 0.5 to 5 MPa.

Since the layer (1) is formed by a silicone resin in an A stage (uncured) state, the two-layer silicone resin sheet of the present invention easily softens at the temperature mentioned above and solidifies thereafter. Therefore, even in the case of LEDs that are connected by gold wires, encapsulation can be achieved without deforming the gold wires.

In a case where the viscosity in the A stage (uncured state) becomes too low at the time of heating, the resin sheet can be left under the conditions of a temperature of 50° C. to 100° C. until the desired viscosity is achieved to promote the reaction beforehand. This provides an option among the embodiments available within the scope of the present invention.

Further, the features of the present invention comprise the two layers of the silicone resin compositions (1) and (2), in which the silicone resin composition (2) contains the (D) component (phosphors), and the silicone resin composition (1) contains the (G) component (white pigment) and has been cured. Here, “softening temperature” means the temperature at which the resin softens, i.e., a softening point. In the present invention the term means the softening temperature measured by, among various methods, the penetration method (a method in which the embedding process of a needle into the resin is observed, and the softening temperature is determined from the deformation of the sample) in thermomechanical analysis (TMA) using a device such as a SS6100 manufactured by Seiko Instrument Inc. The softening temperatures of the silicone resin compositions (1) and (2) are generally 35 to 100° C., and are preferably in the range of 40 to 80° C.

The curing of the silicone resin compositions (1) and (2) is performed generally at 80 to 200° C., preferably at 90 to 180° C., for 1 to 30 min, more preferably for 2 to 10 min. Furthermore, a postcuring at 100 to 200° C., preferably 110 to 180° C., for 0.1 to 10 h, particularly for 1 to 8 h may be performed.

### EXAMPLES

Although, hereunder, by presenting Synthesis examples, Preparation examples, Examples and Comparative examples, the present invention is described in detail, the present invention is in no way limited to the Examples described below. In the following examples, the viscosities are evaluated at 25° C. Furthermore, the weight-average molecular weights are polystyrene-equivalent values as measured by gel permeation chromatography (GPC).

### Synthesis Example 1

### Vinyl Group Containing Organopolysiloxane Resin (A1)

Following dissolution of an organosilane represented by PhSiCl₃:27 mol, ClMe₂SiO(Me₂SiO)₃₃SiMe₂Cl:1 mol, and MeViSiCl₂:3 mol in a toluene solvent, the toluene solution was added dropwise into water. The resulting mixture was subjected to co-hydrolysis, washing with water, neutralization with alkali, removing water, and the solvent stripping to obtain a synthesized vinyl group-containing resin (A1). The composition of this resin in terms of the constituent siloxane units and the structural unit represented by [—SiMe₂O-(Me₂SiO)₃₃—SiMe₂O_{2/2}] is given by the formula: [PhSiO_{3/2}]_{0.27}[—SiMe₂O-(Me₂SiO)₃₃—SiMe₂O_{2/2}]_{0.01}—[MeViSiO_{2/2}]_{0.03}. The weight-average molecular weight of this resin was 62,000, and the melting point was 60° C.

### Synthesis Example 2

### Hydrosilyl Group-Containing Organopolysiloxane Resin (B1)

Following dissolution of an organosilane represented by PhSiCl₃: 27 mol, ClMe₂SiO(Me₂SiO)₃₃SiMe₂Cl:1 mol, and MeHSiCl₂:3 mol in a toluene solvent, the toluene solution was added dropwise into water. The resulting mixture was subjected to co-hydrolysis, washing with water, neutralization with alkali, removing water, and a solvent stripping to obtain a synthesized hydrosilyl group-containing resin (B1). The composition of this resin in terms of the constituent siloxane units and the structural unit represented by [—SiMe₂O-(Me₂SiO)₃₃—SiMe₂O_{2/2}] is given by the formula: [PhSiO_{3/2}]_{0.27}[—SiMe₂O-(Me₂SiO)₃₃—SiMe₂O_{2/2}]_{0.01}[MeViSiO_{2/2}]_{0.03}. The weight-average molecular weight of this resin was 58,000, and the melting point was 58° C.

### Synthesis Example 3

### Vinyl Group-Containing Organopolysiloxane Resin (A2)

Following dissolution of an organosilane represented by PhSiCl₃: 27 mol, ClMe₂SiO(Me₂SiO)₃₃SiMe₂Cl:1 mol, and Me₂ViSiCl:3 mol in a toluene solvent, the toluene solution was added dropwise into water. The resulting mixture was subjected to co-hydrolysis, washing with water, neutralization with alkali, removing water, and a solvent stripping to obtain a synthesized vinyl group-containing resin (A2). The composition of this resin in terms of the constituent siloxane units and the structural unit represented by [—SiMe₂O-(Me₂SiO)₃₃—SiMe₂O_{2/2}] is given by the formula: [PhSiO_{3/2}]_{0.27}[—SiMe₂O-(Me₂SiO)₃₃—SiMe₂O_{2/2}]_{0.01}[Me₂ViSiO_{1/2}]_{0.03}. The weight-average molecular weight of this resin was 63,000, and the melting point was 63° C.

### Synthesis Example 4

### Hydrosilyl Group-Containing Organopolysiloxane Resin (B2)

Following dissolution of an organosilane represented by PhSiCl₃: 27 mol, ClMe₂SiO(Me₂SiO)₃₃SiMe₂Cl:1 mol, and Me₂HSiCl:3 mol in a toluene solvent, the toluene solution was added dropwise into water. The resulting mixture was subjected to co-hydrolysis, washing with water, neutralization with alkali, removing water, and a solvent stripping to obtain a synthesized hydrosilyl group-containing resin (B2). The composition of this resin in terms of the constituent siloxane units and the structural unit represented by [—SiMe₂O-(Me₂SiO)₃₃—SiMe₂O_{2/2}] is given by the formula: [PhSiO_{3/2}]_{0.27}[—SiMe₂O-(Me₂SiO)₃₃—SiMe₂O_{2/2}]_{0.01}[Me₂HSiO_{1/2}]_{0.03}. The weight-average molecular weight of this resin was 57,000, and the melting point was 56° C.

### Preparation Example 1

### Preparation Example of the Phosphor-Containing Silicone Resin Composition (2)

To 90 parts by mass of a base composition containing the vinyl group-containing organopolysiloxane resin (A1) of Synthesis example 1: 189 g, the hydrosilyl group-containing organopolysiloxane resin (B1) of Synthesis Example 2: 189 g, ethynylcyclohexanol, an acetylene alcohol used as a reaction inhibitor:0.2 g, and an octyl alcohol-modified solution of chloroplatinic acid: 0.1 g, 10 parts by mass of a 5 μm particle sized (average particle diameter) phosphor (YAG) was further added to the base composition. The mixture was thoroughly stirred in a warmed planetary mixer at 60° C. to prepare the silicone resin composition (2). This composition (2) was a plastic solid at 25° C. The softening point of the obtained composition measured by the penetration method [utilized device: SS6100 manufactured by Seiko Instrument Inc] was 60° C. Further, as for a cured product of such composition that has been cured under a condition of 150° C./5 min, the hardness thereof was 20 when measured by a D-type testing machine. However, the composition failed to cure under a condition of 80° C./30 min.

### Preparation Example 2

### Preparation Example of the White Pigment-Containing Silicone Resin Composition (1)

Added to 50 parts by mass of a polysiloxane (VF) represented by the following formula (1) were: 50 parts by mass of a resin-structured vinylmethylsiloxane (VMQ) consisting of 50 mol % of SiO₂ units, 42.5 mol % of (CH₃)₃SiO_{0.5} units and 7.5 mol % of Vi₃SiO_{0.5} units; an organohydrogenpolysiloxane represented by the following formula (ii) in such an amount that the SiH therein amounts to 1.5 times larger, in terms of moles, than a total amount of the vinyl groups in the VF and VMQ components; and 0.05 parts by mass of an octyl alcohol-modified solution of chloroplatinic acid. A mixture thus prepared was then thoroughly stirred using a planetary mixer, followed by being dispersed with a triple roll mill, thus obtaining a dispersed silicone resin composition. Next, the composition thus obtained was heated and molded into a cured product under a condition of 150° C./4 hr. Here, the cured product exhibited a hardness of 60 when measured by an A-type spring testing machine that is compliant with JIS K 6301. Further, to 100 parts by mass of the aforementioned composition was added 1 part by mass of a titanium oxide (PF-691 manufactured by Ishihara Sangyo Kaisha Ltd.), followed by thoroughly stirring a mixture thus prepared with a planetary mixer and then dispersing the resulting mixture using a triple roll mill, thus obtaining a silicone resin composition (1). This composition (1) cured under a condition of 80° C./3 min, and turned into a rubber-like product.

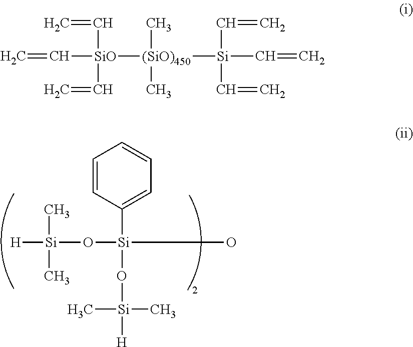

### Preparation Example 3

### Comparative Preparation Example

### Preparation of a Silicone Resin Composition (1′) Containing No Phosphors and No White Pigment

Added to 50 parts by mass of a polysiloxane (VF) represented by the following formula (i) were: 50 parts by mass of a resin-structured vinylmethylsiloxane (VMQ) consisting of 50 mol % of SiO₂ units, 42.5 mol % of (CH₃)₃SiO_{0.5} units and 7.5 mol % of Vi₃SiO_{0.5} units; an organohydrogenpolysiloxane represented by the following formula (ii) in such an amount that the SiH therein amounts to 1.5 times larger, in terms of moles, than a total amount of the vinyl groups in the VF and VMQ components; and 0.05 parts by mass of an octyl alcohol-modified solution of chloroplatinic acid. A mixture thus prepared was then thoroughly stirred using a planetary mixer, followed by dispersing with a triple roll mill, thus obtaining a silicone resin composition (1′). Next, the composition thus obtained was heated and molded into a cured product under a condition of 150° C./4 hr. Here, the cured product exhibited a hardness of 60 when measured by an A-type spring testing machine that is compliant with ES K 6301. This composition turned into a rubber-like product when cured under the condition of 80° C./3 min.

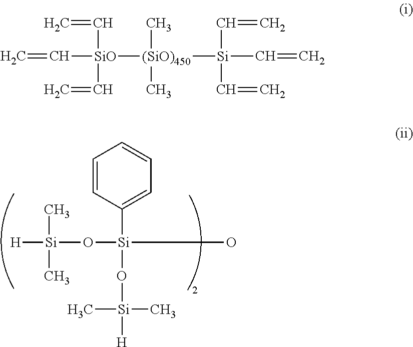

### Preparation Example 4

### Comparative Preparation Example

### Preparation of a Phosphor-Containing Silicone Resin Composition (2′)

To 70 parts by mass of, instead of the vinyl group-containing organopolysiloxane (A1) prepared in Synthesis example 1, a commercially available addition reaction-curable silicone varnish KJR-632L-1 (the brand name, manufactured by Shin-Etsu Chemical Co. Ltd.), which has, as the main component, a vinyl group-containing organopolysiloxane resin containing no linear diorganopolysiloxane chain structure with a number of repeating units of 5 to 300 and is liquid at room temperature, 30 parts by mass of the 5 μm particle sized (average particle diameter) phosphor (YAG) as used in Example 1 was added, and the mixture was thoroughly stirred in a warmed planetary mixer at 60° C. to prepare a silicone resin composition (2′).

### Example 1

### (1) Production of White Pigment-Containing Silicone Resin Sheet

The silicone resin composition (1) of Preparation example 2 was sandwiched between two sheets of an EFTE film (manufactured by Asahi Glass Co., the brand name: Aflex), subjected to compressive molding using a hot pressing machine at 80° C. under a pressure of 5 t for 5 min, and molded into a sheet-like cured product with a thickness of 100 μm with the release films attached to the both faces.

### (2) Production of Phosphor-Containing Silicone Resin Sheet

The silicone resin composition (2) of Preparation example 1 was sandwiched between two sheets of an EFTE film (manufactured by Asahi Glass Co., the brand name: Aflex) (hereunder referred to as the “release film”), subjected to compressive molding using a hot pressing machine at 80° C. under a pressure of 5 t for 5 min, and molded into a sheet form with a thickness of 50 μm with the release films attached to the both faces.

### (3) Preparation of Two-Layer Silicone Resin Sheet

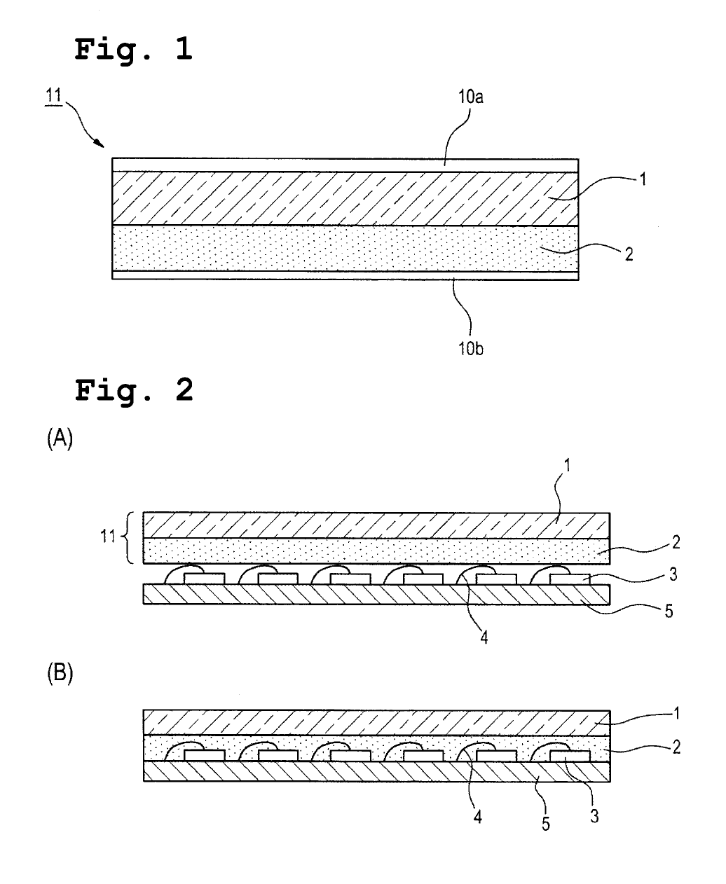

One of the release films of the phosphor-containing silicone resin sheet prepared in the step (2) above was detached, and one of the release films of the cured white pigment-containing silicone resin sheet prepared in (1) was detached. Opposing the exposed resin faces of the respective sheets, they were bonded together in a state of no voids or gaps between the sheets by pressurizing at a temperature of 40° C. with a sheet assembly equipment. The obtained two-layer silicone resin sheet was, as shown in FIG. 1, a sheet 11 in which the release films 10a and 10b were bonded to the outer face of each of the phosphor-containing silicone resin layer (2) and the heat-cured white pigment-containing silicone resin layer (1).

### Example 2

### Encapsulation of LED Element on Ceramic Substrate

The two-layer heat-curable silicone resin sheet obtained in Example 1 with the release films thereon was cut into small pieces of a chip size as shown in FIG. 4A. Following detachment of the release film 10b from one face of the sheet piece, the piece was mounted on a GaN-based LED element 3 so that the exposed phosphor-containing silicone resin face contacts the LED chip, and then the release film 10a was removed from the other face. Subsequently, upon heating at 150° C. for 5 minutes, the phosphor-containing resin layer 2 of the silicone resin sheet on the LED element 3 softened to coat the entire element before curing. Thus, as shown in FIG. 4B, there were formed the phosphor-containing resin layer 2 and white pigment-containing silicone resin layer 1 coating the LED element 3. Here, although the white pigment-containing silicone resin layer 1 does not soften, it can be easily deformed due to the rubber-like property thereof. In fact, the white pigment-containing silicone resin layer 1 deformed following the deformation of the phosphor-containing resin layer 2. Secondary curing was performed by further heating the primarily cured layers at 150° C. for 60 min. In this manner, a light emitting semiconductor (LED) device with a flip-chip structure coated with the phosphor-containing silicone resin layer 2 and the white pigment-containing silicone resin layer 1 was prepared (FIG. 4B). In the drawing, 9 is a gold bump, and 8 represents a silicone underfill material containing 60 mass % of silica. The three LED elements each emitting light were prepared as samples, and the chromaticity coordinates were measured with an LED optical characteristics monitor (LE-3400) manufactured by Ohtsuka Electronics Co. The average value of the measured values of the three samples was obtained.

### Example 3

### Encapsulation of LED Element Mounted Inside Reflector

Using the two-layer heat-curable silicone resin sheet obtained in Example 1 in order to encapsulate the GaN-based LED element 3 mounted in the reflector 6 shown in FIG. 3A and FIG. 3B, the resin sheet was cut into chip-sized small pieces including the release film, as shown in FIG. 3A. Meanwhile the LED element 3 was bonded with a silicone resin die-bond agent to and inside the reflector 6, and then was connected to an external electrode (not shown in the drawing) with the gold wire 4.

Following detachment of the release film from one face of the obtained sheet piece 11, the piece 11 was mounted on a GaN-based LED element 3 so that the exposed phosphor-containing silicone resin layer 2 surface contacts the LED chip, and then the release film was removed from the other face. Subsequently, upon heating for 5 min at 150° C., the phosphor-containing resin layer 2 of the silicone resin sheet softened on the LED element 3 to coat the entire element before curing. Thus, as shown in FIG. 3B, there were formed the phosphor-containing resin layer 2 and white pigment-containing silicone resin layer 1 coating the LED element 3. Here, although the white pigment-containing silicone resin layer 1 does not soften, it can be easily deformed due to the rubber-like property thereof. In fact, the white pigment-containing silicone resin layer 1 deformed following the deformation of the phosphor-containing resin layer 2. Secondary curing was performed by further heating the primarily cured layers at 150° C. for 60 min. In this manner, a reflector-installed light emitting semiconductor (LED) device coated with the phosphor-containing silicone resin layer 2 and the white pigment-containing silicone resin layer 1 obtained was prepared (FIG. 3B). Three samples of LED elements each emitting light were prepared, and the chromaticity coordinates were measured with an LED optical characteristics monitor (LE-3400) manufactured by Ohtsuka Electronics Co. The average value of the measured values of the three samples was obtained.

### Comparative Example 1

### (1) Preparation of Phosphor-Containing Silicone Resin Sheet

The composition of Preparation example 1 was sandwiched between two sheets of the release film, subjected to compressive molding using a hot pressing machine at 80° C. under a pressure of 5 t for 5 min, and molded into a sheet form with a thickness of 50 μm with the release films attached to the both faces of the sheet.

### (2) Encapsulation of LED Element on Ceramic Substrate

The phosphor-containing layer heat-curable silicone resin sheet obtained in the step (1) with the release films on it was cut into small pieces of a chip size. Following detachment of the release film from one face of the obtained sheet piece, the piece was mounted on a GaN-based LED element 3 so that the exposed phosphor-containing silicone resin face contacts the LED chip, and then the release film was removed from the other face. During the subsequent heating for 5 min at 150° C., the silicone resin sheet on the LED element softened to coat the entire element and form the cured phosphor-containing resin layer. Secondary curing was performed by further heating the primarily cured layer at 150° C. for 60 min. In this manner a light emitting semiconductor (LED) device with a flip-chip structure coated with only the phosphor-containing silicone resin layer was prepared. Three samples of LED elements each emitting light were prepared, and the chromaticity coordinates were measured with an LED optical characteristics monitor (LE-3400) manufactured by Ohtsuka Electronics Co. The average value of the measured values of the three samples was obtained.

### Comparative Example 2

### (1) Production of Phosphor-Containing Silicone Resin Sheet

The composition (2) of Preparation example 1 was sandwiched between two release films, subjected to compressive molding using a hot pressing machine for 5 min under a pressure of 5 t at 80° C., and then molded into a sheet form with a thickness of 50 with the PET films attached to the both faces of the sheet.

### (2) Production of Transparent Silicone Resin Sheet

The composition (1′) of Preparation example 3 was sandwiched between two release films, subjected to compressive molding using a hot pressing machine at 80° C. under a pressure of 5 t for 5 min, and then molded into a sheet-like cured product with a thickness of 50 μm with the respective films attached to the two faces of the product.

### (3) Production of Two-Layer Silicone Resin Sheet

One of the release films of the phosphor-containing silicone resin sheet prepared in the step (1) and one of the release films of the transparent silicone resin sheet prepared in the step (2) were detached. Opposing the exposed resin faces of the respective sheets, they were bonded together in a state of no voids or gaps between the sheets by pressurizing them at a temperature of 40° C. with a sheet assembly equipment. As shown in FIG. 1, the obtained two-layer silicone resin sheet was the sheet 11 with the release films 10a and 10b adhering to the outer side of each of the phosphor-containing silicone resin layer 2 and the transparent silicone resin layer 1′.

### (4) Encapsulation of LED Element on Ceramic Substrate

The two-layer heat-curable silicone resin sheet obtained in the step (3) with the release films on it was cut into small pieces of a chip size, as shown in FIG. 4A. Following detachment of the release film from one face of the obtained sheet piece, the piece was mounted on a GaN-based LED element 3 so that the surface of the exposed phosphor-containing silicone resin layer 2 contacts the LED chip, and then the release film was removed from the other face. Subsequently, upon heating for 5 min at 150° C., the silicone resin sheet on the LED element softened to coat the entire element before forming the phosphor-containing resin layer 2 and the transparent silicone resin layer 1′ through curing. Secondary curing was performed by further heating the primarily cured layer at 150° C. for 60 min. In this manner a light emitting semiconductor (LED) device with a flip-chip structure coated with the obtained phosphor-containing silicone resin layer 2 and the transparent silicone resin layer 1′ was prepared. In FIG. 4A and FIG. 4B, 9 represents a gold bump, and 8 represents a silicone underfill material containing 60 mass % of silica. Three samples of LED elements each emitting light were prepared, and the chromaticity coordinates were measured with an LED optical characteristics monitor (LE-3400) manufactured by Ohtsuka Electronics Co. The average value of the measured values of the three samples was obtained.

### Comparative Example 3

A GaN-based LED element 3 was bonded with a silicone resin die-bond agent to and inside the reflector 6, and then connected to an external electrode with a gold wire 4. Next, the silicone resin composition (2′) prepared in Preparation example 4 was injected in an amount sufficient to coat the entire interior of the reflector, and cured at 60° C. for 30 min, 120° C. for 1 h, and further at 150° C. for 1 h to prepare a light emitting semiconductor device. The three samples of LED elements each emitting light were prepared, and the chromaticity coordinates were measured by means of an LED optical characteristics monitor (LE-3400) manufactured by Ohtsuka Electronics Co. The average value of the measured values of the three samples was obtained.

### (Property Evaluations)

•Dispersion Properties of Phosphor within Two-Layer Silicone Sheet

Following curing 10 cm×10 cm samples of the two-layer silicone sheets prepared in Example 1 at 120° C. for 30 min and 150° C. for 1 h, the thickness each of the phosphor layer and white pigment layer was measured by a microscope for one hundred pieces cut out from the cured sheets and each having a size of 1 cm×1 cm. As a result, the thickness of the phosphor layer was controlled within a range of 48 to 51 μm, and the thickness of the white pigment layer was controlled within a range of 98 to 102 μm.

### •Adhesion Force Between Two-Layer Silicone Sheet

In order to measure the adhesion force between the two types of silicone sheets, i.e., the phosphor-containing silicone resin sheet and phosphor-free white pigment-containing silicone resin sheet that respectively form the phosphor layer and the white pigment layer, the silicone resin sheet composed of two layers and obtained in Example 1 was cured at 120° C. for 30 min and at 150° C. for 1 h. Thereafter, the phosphor layer and the white pigment layer were tried to peel off from each other. The two layers, however, were bonded so tightly that a cohesive failure occurred in the phosphor layer and the white pigment layer.

•Dispersion Properties of Phosphor within Light Emitting Semiconductor Device

In order to confirm the dispersion properties of the phosphors within a light emitting semiconductor device, ten pieces of each of the encapsulated elements inside the reflectors mounted on in the light emitting semiconductor devices prepared in Example 3 and Comparative example 3 were cut out, and the thicknesses of the phosphor layers of the pieces above the LED element were measured by a microscope. As a result, the phosphor layer uniformly dispersed with a thickness of 48 to 51 μm above the LED element surface in the case of Example 3, which utilized the two-layer silicone sheet. In contrast, in the case of Comparative example 3, there was observed an uneven distribution of the phosphors, in which the phosphors were present at the level of approximately 100 μm above the LED element surface, and the closer to the LED element, the higher was the phosphor density.

### •Measurement of Chromaticity Coordinates

Three samples of each of the light emitting semiconductor devices prepared in Examples 2 and 3 were prepared, and the chromaticity coordinates were measured by an LED optical characteristics monitor (LE-3400) manufactured by Ohtsuka Electronics Co. The average value of the measured values of the three samples was obtained. (Note: u′, v′: CIE 1976 chromaticity coordinates is based on the calculation method described in JIS Z 8726.)

TABLE 1

Chromaticity Coordinate

| | u′ | v′ |
|---|---|---|
| Example 2 | 0.209 | 0.459 |
| Example 3 | 0.209 | 0.478 |
| Comparative example 1 | 0.209 | 0.408 |
| Comparative example 2 | 0.209 | 0.412 |

Comparing the values of v′ of the light measured for Examples 2 and 3 with that for Comparative example 1, the values of v′ for Examples 2 and 3 were larger than the value for Comparative example 1. Furthermore, comparing the values of v′ for Examples 2 and 3 with that for Comparative example 2, the values of v′ of the light measured for Examples 2 and 3 were larger than the latter value. From this, the value of v′ can be increased by incorporating a white layer, which means that a desired whiter light can be achieved with a small amount of phosphors.

Furthermore, comparing the values of v′ of the light measured for Examples 2 and 3, the value of v′ for Example 3 is larger than that for Example 2. From this, the value of v′ can be adjusted by changing the mounting conditions of the white layer.

Generally, increasing the value of v′ requires increasing the amount of the filled phosphors. However, the above-mentioned results shows that by incorporating a white pigment-containing layer, the same value of v′ can be achieved with a smaller amount of phosphors.

### •Deviations in Chromaticity Coordinates

Three samples of each of the light emitting semiconductor devices prepared in Examples 2, 3 and Comparative examples 1 to 3 were prepared, and the deviations in the chromaticity coordinates were measured with LE-3400 manufactured by Ohtsuka Electronics Co. The average value of the measured values of the three samples was obtained.

TABLE 2

Deviation in
Chromaticity Coordinate

| | u′ | v′ |
|---|---|---|
| Example 2 | ±0.002 | ±0.004 |
| Example 3 | ±0.002 | ±0.004 |
| Comparative example 1 | ±0.002 | ±0.004 |
| Comparative example 2 | ±0.002 | ±0.004 |
| Comparative example 3 | ±0.006 | ±0.010 |

Comparing the results of Examples 2 and 3 with the result of Comparative example 1, it is understood that even if a white pigment-containing layer is incorporated, a degree of the variations in the chromaticity coordinates is almost unchanged.

Furthermore, comparing the results of Examples 2 and 3 with the result of Comparative example 3, the variations in Examples 2 and 3 are smaller than that in Comparative example 3. Therefore, it is understood that by using the two-layer silicone resin sheet of the present invention, a light emitting semiconductor device having uniform light emitting characteristics can be obtained without color drift.

The heat-curable silicone resin sheet of the present invention is useful for coating and encapsulating light emitting elements, such as LED elements, and for producing light emitting devices.

What is claimed:

1. A heat-curable silicone resin sheet comprising:
a phosphor-containing layer consisting essentially of a phosphor-containing heat-curable silicone resin composition that is a plastic solid or semi-solid at normal temperate; and
a white pigment-containing layer consisting essentially of a heat-cured white pigment-containing heat-curable silicone resin composition.

2. The heat-curable silicone resin sheet according to claim 1, wherein a thickness of said phosphor-containing layer is 20 to 100 μm, and a thickness of said white pigment-containing layer is 20 to 300 μm.

3. The heat-curable silicone resin sheet according to claim 1, wherein said phosphor-containing layer consists essentially of said heat-curable silicone resin composition comprising:
(A) a resin-structured organopolysiloxane essentially consisting of R¹SiO_{1.5} units, R²₂SiO units and R³ₐR⁴_{b}SiO_{(4-a-b)/2} units, wherein each of R¹, R² and R³ independently represents a monovalent hydrocarbon group having 1 to 10 carbon atoms, R⁴ independently represents an alkenyl group having 2 to 5 carbon atoms, a represents 0, 1 or 2, b represents 1 or 2, and a+b is either 2 or 3, and wherein at least a portion of said R²₂SiO units are consecutively repeated in a repetition number of 5 to 300;
(B) a resin-structured organohydrogenpolysiloxane essentially consisting of R¹SiO_{1.5} units, R²₂SiO units and R³_{c}H_{d}SiO_{(4-c-d)/2} units, wherein R¹, R² and R³ independently represent the aforementioned groups, c represents 0, 1 or 2, d represents 1 or 2, and c+d is either 2 or 3, and wherein at least a portion of said R²₂SiO units are consecutively repeated in the repetition number of 5 to 300, and wherein a molar ratio of the hydrogen atoms bonded to the silicon atoms in the component (B) relative to a sum of the alkenyl groups in the component (A) is in a range of 0.1 to 4.0,
(C) a platinum group metal based catalyst; and
(D) a phosphor,
and wherein said white pigment-containing layer consists essentially of a heat-cured phosphor-free silicone resin composition comprising:
(E) a vinyl group-containing organopolysiloxane;
(F) an organohydrogenpolysiloxane;
(C) a platinum group metal based catalyst; and
(G) a white pigment.

4. The heat-curable silicone resin sheet according to claim 3, wherein the amount of said phosphor as the component (D) in said phosphor-containing layer is in a range of 0.1 to 300 parts by mass per 100 parts by mass of all of the components (A) to (C).

5. The heat-curable silicone resin sheet according to claim 3, wherein the average particle diameter of said phosphor as the component (D) in said phosphor-containing layer is 10 nm or more.

6. The heat-curable silicone resin sheet according to claim 3, wherein the amount of said white pigment as the component (G) in said white pigment-containing layer is in a range of 0.05 to 10 parts by mass per 100 parts by mass of the components (E) and (F).

7. The heat-curable silicone resin sheet according to claim 3, wherein the average particle diameter of said white pigment as the component (G) in said white pigment-containing layer is 50 nm or more.

8. The heat-curable silicone resin sheet according to claim 1, wherein a difference in softening temperature between said white pigment-containing layer and said phosphor-containing layer is within 10° C.

9. A method of producing a light emitting device having an LED element, comprising:
placing on a surface of the LED element the heat-curable silicone resin sheet as set forth in claim 1;
heat-curing said heat-curable silicone resin sheet such that the surface of the LED element can be coated with and encapsulated by a cured product having a phosphor-containing cured silicone resin layer and a white or white semi-transparent cured silicone resin layer that is phosphor-free and contains a white pigment.

10. A light emitting device produced by the method as set forth in claim 9, wherein an LED element is encapsulated by a cured product having:
a phosphor-containing cured silicone resin layer; and
a white or white semi-transparent cured silicone resin layer that is phosphor-free and contains a white pigment.
